(19) United States
(12) Patent Application Publication
(10) Pub. No.: US 2013/0161181 A1
(43) Pub. Date: Jun. 27, 2013

(54) METHOD FOR MANUFACTURING A MAGNETIC RECORDING DISK WITH IMPROVED YIELD

(71) Applicants: Xing-Cai Guo, Tracy, CA (US); Thomas E. Karis, Aromas, CA (US); Bruno Marchon, Palo Alto, CA (US); Franck D. R. dit Rose, San Jose, CA (US); Connie H.T. Wiita, San Jose, CA (US)

(72) Inventors: Xing-Cai Guo, Tracy, CA (US); Thomas E. Karis, Aromas, CA (US); Bruno Marchon, Palo Alto, CA (US); Franck D. R. dit Rose, San Jose, CA (US); Connie H.T. Wiita, San Jose, CA (US)

(73) Assignee: Hitachi Global Storage Technologies Netherlands B.V., Amsterdam (NL)

(21) Appl. No.: 13/333,946

(22) Filed: Dec. 21, 2011

(51) Int. Cl. C23C 14/34

(52) U.S. Cl. 204/192.1; 204/298.02

(57) ABSTRACT

A method for manufacturing a magnetic media for magnetic data recording that greatly reduces the time required to manufacture the magnetic media. After constructing the magnetic disk with the desired magnetic media layer, a protective overcoat is deposited on the disk. The disk is then exposed to ozone in order to speed the rate of oxidation of the protective overcoat and thereby reduce the time needed to treat the overcoat. After exposing the overcoat to an ozone a lubrication layer can be applied. This process reduces the time necessary to cure the overcoat from a time of about 24 hours to a time range of 10 seconds to 30 minutes.

### FIELD OF THE INVENTION

The present invention relates to magnetic data recording and more particularly a method for manufacturing a magnetic media that decreases the time required to manufacture the magnetic disk and increases manufacturing yield.

### BACKGROUND OF THE INVENTION

A key component of a computer is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). When the slider rides on the air bearing, the write and read heads are employed for writing magnetic impressions to and reading magnetic impressions from the rotating disk. The read and write heads are connected to processing circuitry that operates according to a computer program to implement the writing and reading functions.

The magnetic disk has a high coercivity magnetic layer that can be locally magnetized to record a bit of data. The disk may also include a soft magnetic layer beneath the hard magnetic layer. This soft magnetic layer can be used to conduct magnetic flux through the media to the return pole of the magnetic head. In order to prevent corrosion or other damage to the magnetic media, the disk can include a hard non-magnetic protective overcoat. Above this overcoat layer is a lubrication layer that helps to allow the read and write heads to fly over the magnetic disk without damage to the disk or to the read or write heads.

In the highly competitive market for magnetic data storage, manufacturing cost and throughput have become ever more important. Minimizing the time required to produce a component such as a magnetic media greatly decreases the cost of the finished disk drive system. Certain processes have been relatively time consuming, reducing manufacturing rate and increasing cost. For example, the formation of the protective overcoat on the magnetic media has been very time consuming. After depositing the protective overcoat, the overcoat must be cured for a long time before the lubricant can be applied. Failure to allow the necessary curing time has resulted in insufficient protection to the magnetic media. Therefore, there remains a need for processes for reducing the time required to produce components of a magnetic recording system such as a magnetic media.

### SUMMARY OF THE INVENTION

The present invention provides a method for manufacturing a magnetic media that includes constructing a magnetic disk having a magnetic media layer formed thereon, sputter depositing a protective overcoat layer on the magnetic disk, and exposing the protective overcoat to ozone. The method can be performed in a tool that includes a deposition chamber, an exit air lock connected with the deposition chamber such that a disk can be transported from the deposition chamber to the exit air lock, an air inlet connected with the exit air lock, and an ozone generator connected with the air inlet.

This process of exposing the protective coating to ozone greatly reduces the time required to treat the overcoat after deposition. Whereas prior art processes required the protective overcoat to be exposed to atmosphere for up to 24 hours prior to application of the lubricant layer, the present ozone treatment takes only 10 second to 30 minutes to perform. This, of course, greatly reduces the time necessary to manufacture the magnetic media.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an enlarged cross-sectional view of a portion of a magnetic media according to an embodiment of the invention;

FIG. 3 is a schematic illustration of a process for applying and curing a protective overcoat on a magnetic disk;

FIG. 4 is a graph representing the infrared spectrum of the carbon overcoat after exposure to ambient air for different amounts of time. The background spectrum is the spectrum measured immediately after sputter deposition of the disk layers. The carbonyl peak is near 1700 l/cm wave-number. The carbonyl peak area increases with increasing time in air.

FIG. 5 is a graph representing the carbonyl peak area on the left vertical axis and the yield on the right vertical axis, as a function of time in air after sputter. The yield increases with the carbonyl peak area.

FIG. 6 is a graph representing the yield for untreated disks vs. time in air, and for a disk that was treated with ozone to form the carbon overcoat carbonyl oxidation peak equivalent to about 12 hours in air after sputter.

FIG. 7 is the yield plotted as a function of the carbonyl peak area formed by ozone treatment for different amounts of time or different concentration of ozone. The yield increased with increasing carbonyl peak area formed by the ozone treatment of the carbon overcoat.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

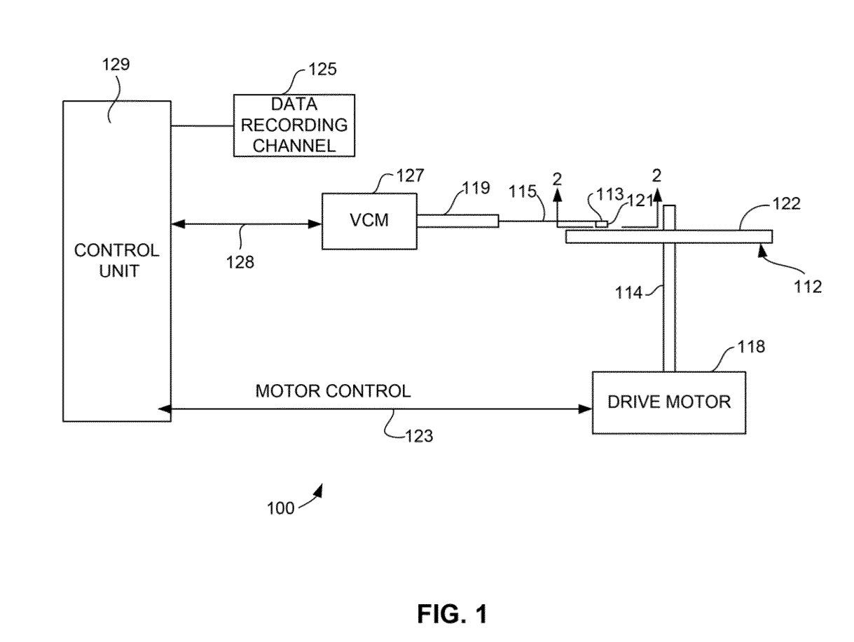

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 can access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

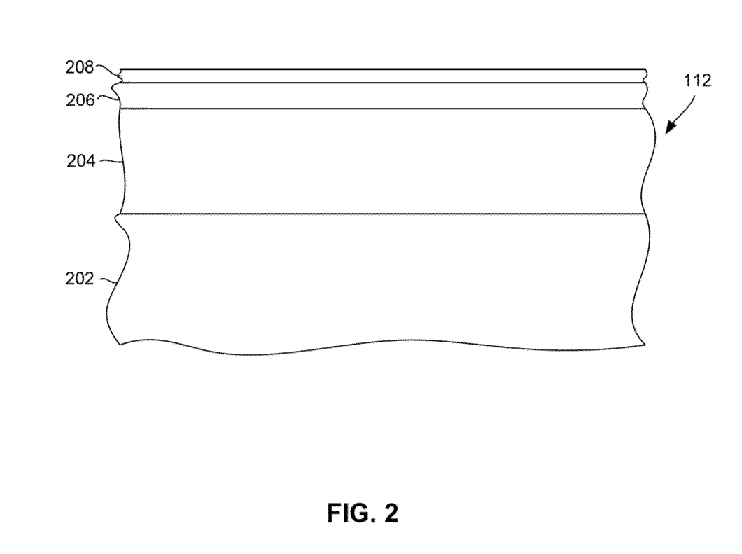

FIG. 2 shows an enlarged cross section of a portion of a magnetic disk 112. The disk includes a substrate 202, a magnetic recording layer 204 formed over the substrate, a protective overcoat 206 formed over the magnetic recording layer and a layer of lubricant 208 formed over the protective overcoat 206. The disk 112 may also include other materials or layers that are not shown for purposes of clarity, such as a soft magnetic under-layer, one or more seed layers, etc.

Magnetic recording density is continuously being increased by decreasing the head media spacing. The spacing reduction is achieved in part by decreasing the lubricant thickness, the protective overcoat thickness, and the surface roughness of the finished media. Throughout this evolution, the disk manufacturing yield must be improved or maintained in order to maintain the disk manufacturing profit margin.

However, with decreasing lubricant and overcoat thickness, and modified thinner overcoats to provide smoother surface topography with while providing adequate corrosion protection, the manufacturing process yield has become increasingly dependent on the time delay between application of the overcoat 206 and application of the lubricant layer 208. In order to achieve acceptable yield, disks have had to be stored for at least 6 hours after application of the protective coating 206 before the lubricant 208 can be applied. This has a negative impact on the manufacturing process flow and adds to the cost of manufacturing the disks 112.

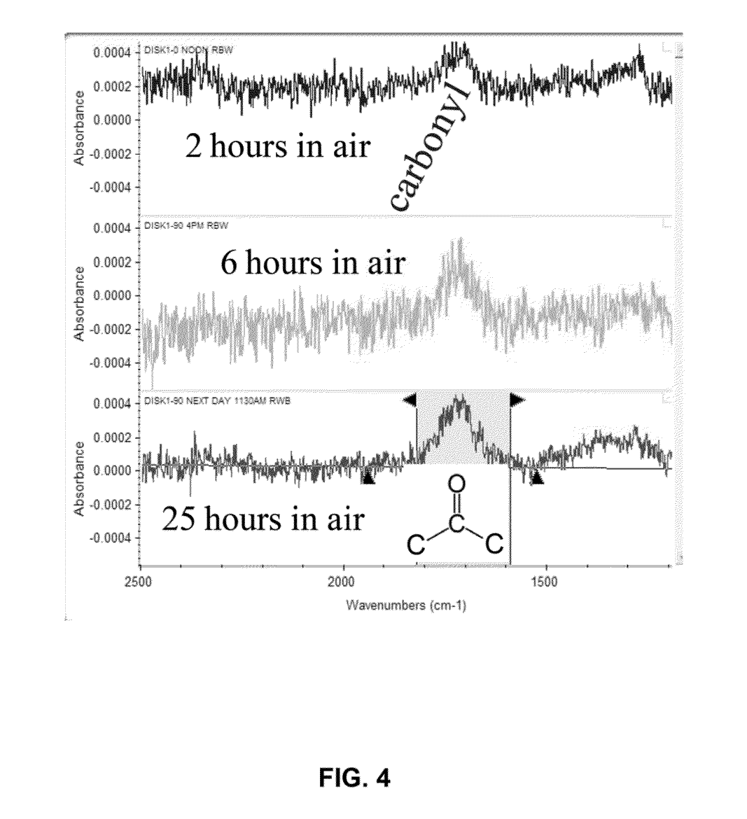

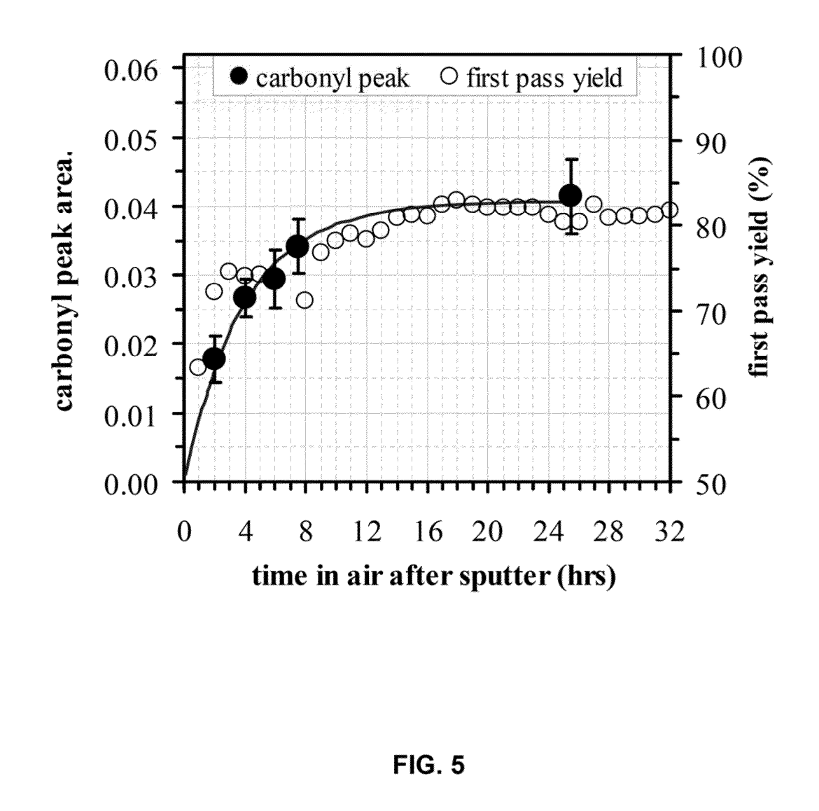

The disc carbon overcoat was studied to determine how the time delay improves yield. The freshly sputtered overcoat is known to contain reactive (dangling) bonds, or carbon radicals. These active groups begin to react with oxygen and moisture when the sputter system exit air lock is vented to atmospheric pressure. Reflection Fourier transform infrared (FTIR) spectroscopy measurements of the disk carbon overcoat indicate the formation of a carbonyl (oxidation) peak with time in air after sputter. FIG. 4 shows the infrared absorption spectrum of wavelength region that includes the overcoat carbonyl oxidation peak. The area under the peak is proportional to molar concentration of carbonyl carbon in the overcoat. The equilibrium level of oxidation after a long time in air or ozone is about 4 at % as determined by x-ray photoelectron spectroscopy. The degree of overcoat oxidation as measured by the carbonyl absorption peak area increases with time in air after sputter as shown in FIG. 5. The overcoat oxidation rate in air is initially rapid (changes within minutes) and then gradually decreases with time over many hours. Also shown in FIG. 5 is the yield, which increases with time along the same curve as the carbonyl peak area.

Further insight into the mechanism of the time delay is provided by the type of defects which are time-dependent. Studies have indicated that the first pass manufacturing glide yield increases as the zonal and hard defect types decrease with time after sputter. Zonal defects are moving defects and generally result from overcoat wear debris. Hard defects are stationary and can result from a disk asperity or a stationary patch of overcoat wear debris. Only the overcoat wear rate is expected to improve with time through partial oxidation of the overcoat surface layer.

The difference in glide yield between long and short time delay results from the lower wear rate of the lubricated carbon overcoat when the overcoat has been allowed time to oxidize before lubrication. This conclusion is deduced from the amount of lubricant removed during polishing (FTP), the polishing friction force, and the root-mean-square (RMS) acoustic emission in a low flying slider sweep test. Even though the ZMTD® lubricant (hydroxyl functionalized perfluoropolyether) will be 91.5 percent bonded on a short time delay disk (minimal oxidation), only 79.3 percent remained after the polishing process. In comparison, the lubricant on an overcoat that was stored in air for 25 hours after sputter deposition of the overcoat 206 was initially 98.2 percent bonded and 92.7 percent remained after the polishing pass.

Therefore, exposure to air after sputter deposition of the carbon overcoat 206 has been an important process in order to produce an overcoat that is robust enough to ensure high yield and long component life and reliability. However, atmospheric exposure for such a great length of time increases the time necessary to construct a disk and therefore greatly reduces throughput and increases manufacturing time. In addition, the necessity to remove the disks from the air lock chamber and store them before adding the lubricant adds additional steps to the process, thereby increasing manufacturing complexity.

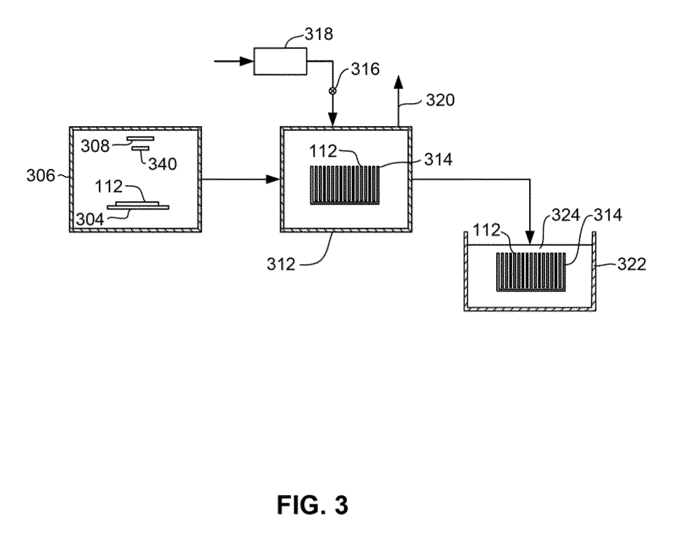

The inventors found a way to achieve the same results as the above described long duration atmospheric exposure much more quickly and without the need to remove the disk from the exit air lock chamber of the sputter deposition tool. This method can be understood with reference to FIG. 3, which shows a schematic illustration of a process for manufacturing a magnetic media (disk) according to an embodiment of the invention. As shown in FIG. 3, in a first step a magnetic disk 112 is held on a chuck 304 within a sputter deposition tool chamber 306. An antenna 308 is provided within the chamber to excite a plasma within the chamber 306 to dislodge atoms from a target 310 which are then deposited onto the disk. In this way, a hard protective layer 206 (FIG. 2) can be deposited onto the disk. Suitable materials for the hard protective layer include diamond like carbon or amorphous carbon, which may incorporate hydrogen and/or nitrogen. Although the present description focuses on the deposition of the hard protective overcoat, other layers of the disk 112 can also be deposited within the chamber 306, such as but not limited to the magnetic recording layer 204 (FIG. 2), by replacing the target 310 with a target of the appropriate material.

After the sputter deposition of the protective overcoat layer 206, the disk is transferred to an exit air lock chamber 312 of the sputter deposition tool. The disk can be held along with many other disks in a cassette 314. It will be recalled that prior art processes required the disks 112 to be exposed to atmosphere for as long as 24 hours. The inventors have, however, found a way to greatly reduce this time requirement.

While the disks 112 are held within the exit air lock, a valve 316 is opened to allow air from the atmosphere to flow into the exit air lock chamber 312. This atmospheric air is passed through an ozone generator 318 so that the air passing into the chamber has a desired concentration of ozone (O₃). Alternatively, pure oxygen O₂ can be passed through the ozone generator 318 into the exit air lock chamber 312 to produce the ozone of desired concentration within the exit air lock chamber 312. The concentration of ozone entering the chamber can be controlled by controlling the flow rate of the air passing through the ozone generator 318. Passing air more slowly through the ozone generator 318 increases the relative amount of ozone in the air entering the chamber 312. Conversely, passing air more quickly through the chamber decreases the relative amount of ozone within the chamber. The chamber 312 can also include an exhaust vent for venting out residual ozone as indicated schematically by arrow 320.

The ozone generator 318 can be a commercially available ozone generator such as Ozone Solutions, Inc. Model OZV-4. The atmosphere within exit airlock chamber can have an ozone concentration of 5 to 50,000 ppm or can be 5% to 50%. The presence of the ozone greatly speeds the oxidation of the overcoat layer 206 (FIG. 2). The disks 112 can be held within this ozone containing atmosphere for 10 seconds to 30 minutes.

After exposure to the ozone containing atmosphere, the disks 112 can be transferred to a bath 322 containing a desired lubricant such as ZTMD® (hydroxy functionalized perfluoropoyether) in order to apply the lubricant to the disks 112. It should be appreciated that while dip coating is described herein as a method for applying lubricant to the disks 112, other methods could be used as well, such as vapor deposition. After application of the lubricant, the disks can be polished (burnished) according to methods that will be familiar to those skilled in the art in order to remove any defects or asperities from the disk.

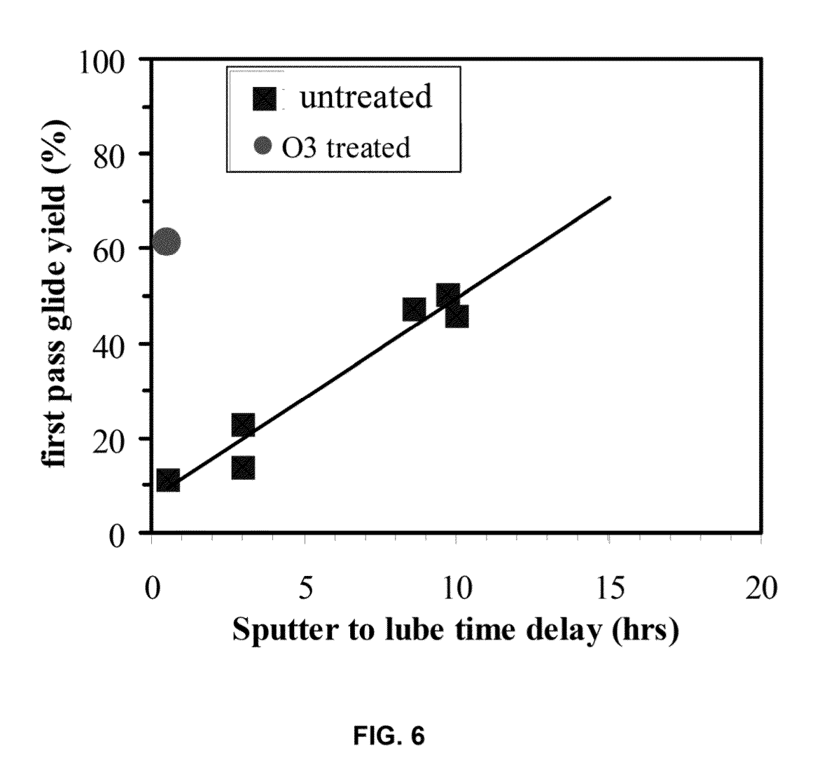

Tests were performed to verify the yield improvement by the ozone treatment. At least 100 disks were used for each data point in these examples tests. In the first example, disks were removed from the sputter tool and some were treated with ozone for 5 minutes at 5,000 ppm, and a control group of disks were left untreated. Both sets of disks were lubricated with 1 nm of ZTMD, polished as usual, and tested for yield. The yield for these two sets of disks are the left most points near time=0 in FIG. 6. The yield for the ozone treated disks was about 60%, while the yield for the untreated disks was about 10%. Other disks from the same batch were stored in ambient (particle-free) air for increasing amounts of time before lubrication. As shown in FIG. 6, the yield increased with increasing storage time in air before lubrication. After about 12 hours in air, the yield has nearly reached the level that was obtained by only 5 minutes of treatment with the ozone.

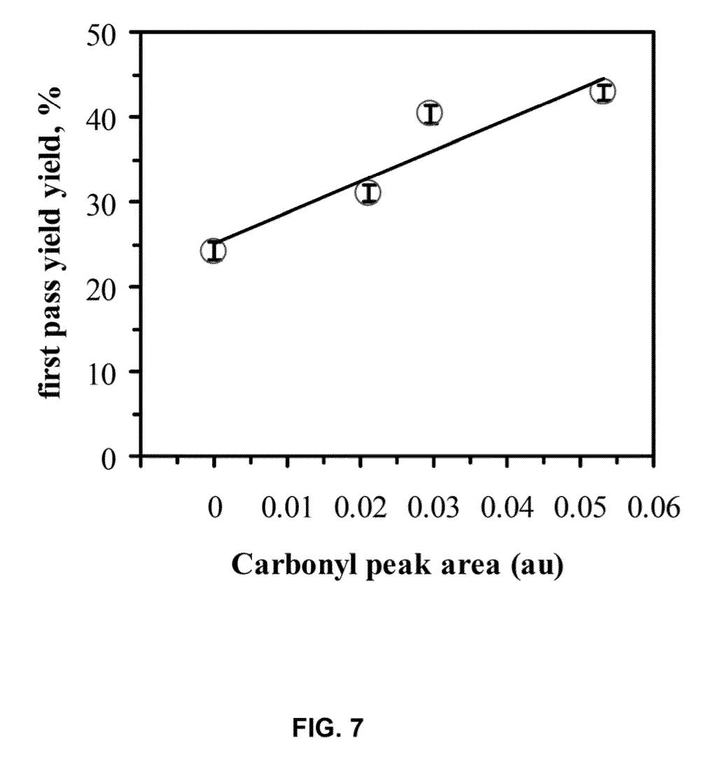

In the second example, disks were collected immediately after sputter and exposed to ozone for various amounts of time between 2 and 5 minutes and ozone concentration from 450 to 5,000 ppm. This provided a set of disks with increasing levels of overcoat carbonyl (oxidation) peak area. These disks were lubricated with 1 nm of ZTMD, polished as usual, and tested for yield. The yield is shown plotted as a function of the carbonyl peak area in FIG. 7. This shows that the yield increases with increasing carbonyl peak area formed by ozone treatment of the carbon overcoat.

While various embodiments have been described above, it should be understood that they have been presented by way of example only and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic media, comprising:
constructing a magnetic disk having a magnetic media layer formed thereon;
sputter depositing a protective overcoat layer on the magnetic disk; and
exposing the protective overcoat to ozone.

2. The method as in claim 1 wherein the sputter deposition is performed in a tool that includes a deposition chamber and an exit air lock, and wherein the deposition of the protective overcoat is performed in the deposition chamber and the exposure of the protective overcoat is performed in the exit air lock.

3. The method as in claim 2 wherein the exit air lock has an ozone generator connected with it, and wherein the exposure of the protective overcoat is performed by passing air from outside the exit air lock through the ozone generator and into the exit air lock.

4. The method as in claim 1 wherein the protective overcoat comprises sputtered or otherwise vacuum deposited carbon containing hydrogen and or nitrogen.

5. The method as in claim 1 where the exposure to ozone is performed in an atmosphere that has an ozone concentration of 5 to 50,000 ppm.

6. The method as in claim 1 wherein the exposure to ozone is performed for a duration of 10 seconds to 30 minutes.

7. The method as in claim I wherein the exposure to ozone is performed in an atmosphere that has an ozone concentration of 5 to 50,000 ppm for a duration of 10 seconds to 30 minutes.

8. The method as in claim 1 further comprising after exposing the protective overcoat to ozone, applying a lubricant to the protective overcoat.

9. The method as in claim 3 further comprising, controlling an air flow through the ozone generator to control an ozone concentration within the exit air lock.

10. The method as in claim 3 further comprising, controlling an air flow through the ozone generator to control an ozone concentration within the exit air lock to attain an ozone concentration of 5 to 50,000 ppm within the exit air lock.

11. The method as in claim I where the exposure to ozone is performed in an atmosphere that has an ozone concentration of 5% to 50%.

12. A tool for manufacturing a magnetic media, comprising:
a deposition chamber;
an exit air lock connected with the deposition chamber such that a disk can be transported from the deposition chamber to the exit air lock;
an air inlet connected with the exit air lock; and
an ozone generator connected with the air inlet.

13. The tool as in claim 12 wherein the ozone generator is configured to provide an ozone concentration of 5-50,000 ppm in the exit air lock.

14. The tool as in claim 12 wherein the ozone generator is configured to provide an ozone concentration of 5% to 50% in the exit air lock.

15. The tool as in claim 12 where the ozone generator feed gas is pure oxygen and the disks are treated with an ozone concentration of 5% to 100% in the exit air lock.

16. The tool as in claim 12 further comprising an exhaust vent for venting out residual ozone.
